(19) United States
(12) Patent Application Publication
(10) Pub. No.: US 2015/0063505 A1
(43) Pub. Date: Mar. 5, 2015

(54) APPARATUS AND METHOD FOR COMPENSATING FOR CHANNEL LOSS IN AN ELECTRONIC DEVICE

(71) Applicant: Samsung Electronics Co., Ltd., Gyeonggi-do (KR)

(72) Inventors: Won-Seob Kim, Seoul (KR); Gyoung-Hwan Park, Gyeongsangbuk-do (KR); Dong-Ho Yu, Gyeonggi-do (KR); Woo-Sung Jang, Gyeonggi-do (KR); Eun-Seok Hong, Gyeonggi-do (KR)

(21) Appl. No.: 14/304,807

(22) Filed: Jun. 13, 2014

(30) Foreign Application Priority Data
Aug. 28, 2013 (KR) 10-2013-0102620

(51) Int. Cl. H04B 7/08; H03G 1/00

(52) U.S. Cl. CPC H04B 7/084; H03G 1/0017
USPC 375/345

(57) ABSTRACT

An apparatus for compensating for channel loss in an electronic includes a resistor configured to increase an output voltage swing level, and a connector configured to receive a data signal, to compensate for channel loss of the received data signal by amplifying the received data signal, and to output the amplified data signal.

### CROSS-REFERENCE TO RELATED APPLICATION(S) AND CLAIM OF PRIORITY

The present application is related to and claims the benefit under 35 U.S.C. §119(a) of a Korean patent application filed in the Korean Intellectual Property Office on Aug. 28, 2013 and assigned Serial No. 10-2013-0102620, the entire disclosure of which is incorporated herein by reference.

### TECHNICAL FIELD

The present disclosure relates generally to an electronic device, and more particularly, to a method and apparatus for compensating for channel loss in an electronic device.

### BACKGROUND

Portable terminals such as smart phones and table Personal Computers (PCs) provide many useful functions to users by various applications. The portable terminals are now evolving to devices that allow users to use various types of information through applications, in addition to a voice call function. Particularly, these portable terminals are connected to external devices and transmit data to or receive data from the external devices by a data input/output function.

To provide the data input/output function, a portable terminal should be connected to an external device in a specific communication scheme. The specific communication scheme may be Universal Serial Bus (UBS) communication.

The above information is presented as background information only to assist with an understanding of the present disclosure. No determination has been made, and no assertion is made, as to whether any of the above might be applicable as prior art with regard to the present disclosure.

### SUMMARY

In USB communication, an electronic device transmits a data signal to an external device via a connector of the electronic device. However, the data signal is transferred from a controller to the connector via a line in the electronic device and thus experiences channel loss. As a result, the data signal is damaged.

To address the above-discussed deficiencies, it is a primary object to provide an apparatus and method for compensating for channel loss by means of a channel loss compensator configured to compensate for channel loss caused by a transmission line of a data signal in an electronic device.

In accordance with certain embodiments of the present disclosure, there is provided an apparatus. The apparatus includes a resistor configured to increase an output voltage swing level, and a connector configured to receive a data signal, to compensate for channel loss of the received data signal by amplifying the received data signal, and to output the amplified data signal.

In accordance with certain embodiments of the present disclosure, there is provided a method for compensating for channel loss in an electronic device. The method includes increasing an output voltage swing level, receiving a data signal, compensating for channel loss of the received data signal by amplifying the received data signal, and outputting the amplified data signal through a connector.

Other aspects, advantages, and salient features of the disclosure will become apparent to those skilled in the art from the following detailed description, which, taken in conjunction with the annexed drawings, discloses embodiments of the disclosure.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates a configuration of a communication system according to embodiments of the present disclosure;

FIG. 2 is a block diagram of an electronic device according to embodiments of the present disclosure;

FIGS. 3A and 3B illustrate boards of electronic devices according to embodiments of the present disclosure;

FIG. 4 illustrates a chip on which a channel loss compensator is implemented according to embodiments of the present disclosure;

FIG. 5 illustrates a circuit diagram of a channel loss compensator according to embodiments of the present disclosure;

FIG. 6 illustrates a method for compensating for channel loss according to embodiments of the present disclosure; and

FIG. 7 illustrates a channel loss compensation effect according to embodiments of the present disclosure.

Throughout the drawings, like reference numerals will be understood to refer to like parts, components, and structures.

### DETAILED DESCRIPTION

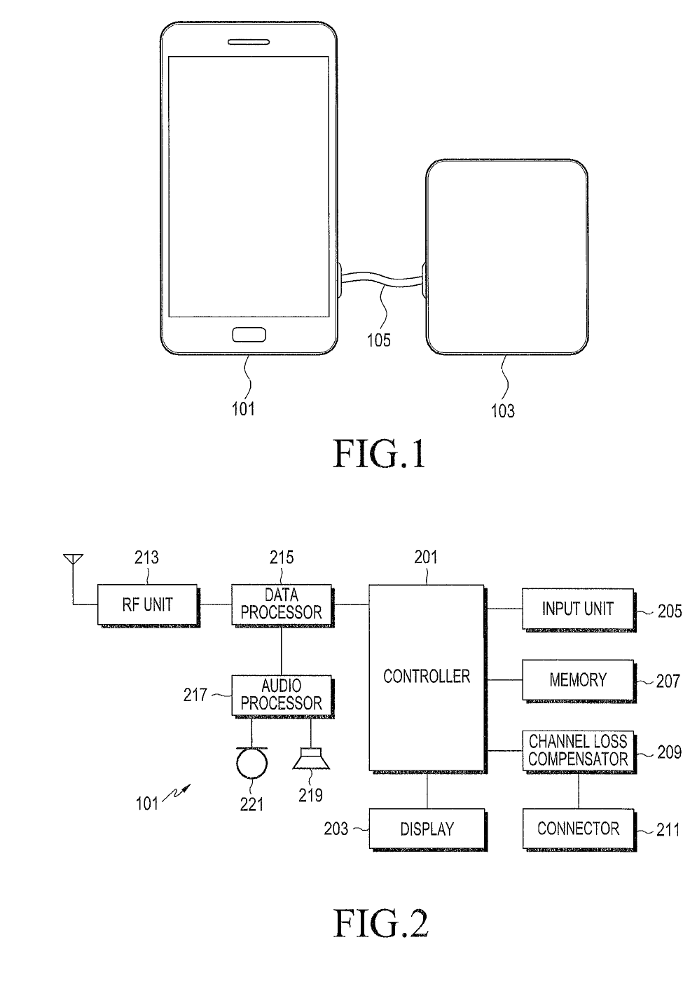

FIGS. 1 through 7, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged wireless communication device. The following description with reference to the accompanying drawings is provided to assist in a comprehensive understanding of embodiments of the disclosure as defined by the claims and their equivalents. It includes various specific details to assist in that understanding but these are to be regarded as merely examples. Accordingly, those of ordinary skilled in the art will recognize that various changes and modifications of the embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of embodiments of the present disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

An electronic device according to embodiments of the present disclosure refers to a mobile electronic device that is readily carried with a user. For example, the electronic device can be one or a combination of two or more of various devices such as video phone, portable phone, smart phone, International Mobile Telecommunication 2000 (IMT-2000) terminal, Wideband Code Division Multiple Access (WCDMA) terminal, Universal Mobile Telecommunications System (UMTS) terminal, Personal Digital Assistant (PDA), Portable Multimedia Player (PMP), Digital Multimedia Broadcasting (DMB) terminal, e-Book reader, portable computer (e.g., laptop, tablet, and the like), digital camera, and the like. It will be apparent to those of ordinary skill in the art that the electronic device according to embodiments of the present disclosure is not limited to the aforementioned devices.

FIG. 1 illustrates a configuration of a communication system according to embodiments of the present disclosure.

Referring to FIG. 1, the communication system includes an electronic device 101, an external device 103, and a cable 105 that connects the electronic device 101 to the external device 103.

The cable 105 connects the electronic device 101 to the external device 103. The cable 105 may transmit a data signal from the electronic device 101 to the external device 103 or from the external device 103 to the electronic device 100 in a specific communication scheme supported by the electronic device 101 and the external device 103. For example, the specific communication scheme can be Universal Serial Bus (USB) communication. The USB communication has evolved gradually from USB 1.0 to USB 3.0. The specific communication scheme can be USB 3.0.

The external device 103 is connected to the electronic device 101 via the cable 105, The external device 103 may transmit a stored data signal to the electronic device 101 or receive a data signal from the electronic device 101. The external device 103 can be any of Television (TV), monitor, beam projector, keyboard, touch screen, keyboard, Personal Computer (PC), audio player, auxiliary battery, and the like.

The electronic device 101 is connected to the external device 103 via the cable 105. The electronic device 101 transmits a stored data signal with channel loss compensated for to the external device 103.

FIG. 2 is a block diagram of an electronic device according to embodiments of the present disclosure.

Referring to FIG. 2, the electronic device 101 includes a controller 201, a display 203, an input unit 205, a memory 207, a channel loss compensator 209, a connector 211, a Radio Frequency (RF) unit 213, a data processor 215, and an audio processor 217.

The RF unit 213 performs a wireless communication function of the electronic device 101. Specifically, the RF unit 213 includes an RF transmitter that upconverts the frequency of a transmission signal and amplifies the upconverted transmission signal and an RF receiver that low-noise-amplifies a received signal and downconverts the low-noise-amplified signal. The data processor 215 includes a transmitter that encodes and modulates a transmission signal and a receiver that demodulates and decodes a received signal. The data processor 215 can include two Modulators-Demodulators (MODEMS) and two Coders-Decoders (CODECs). The CODECs can be a data CODEC that processes a packet data signal and an audio CODEC that processes an audio signal such as voice.

The audio processor 217 reproduces an audio signal received from the data processor 215 through a speaker 219 or transmits an audio signal generated from a microphone 221 to the data processor 215. The input unit 205 includes alphanumerical keys used to enter numerals and characters and function keys. The display 203 displays an image signal on a screen, and displays a data signal upon request of the controller 201.

If the display 203 is implemented as a capacitive or resistive touch screen, the input unit 205 can include a minimum number of predetermined keys and the display 203 can take over a part of a key input function of the input unit 205.

The memory 207 may include a program memory and a data memory. The program memory stores a booting program and an Operating System (OS) to control general operations of the electronic device 101 and the data memory stores data signals generated during operations of the electronic device 101.

The connector 211 connects the electronic device 101 to the external device 103 via the cable 105. The connector 211 can be a USB connector or a connector supporting USB communication and any other communication (e.g., Mobile High-Definition Link (MHL) communication).

The controller 201 provides overall control to the electronic device 101. Particularly, the controller 201 transmits a data signal stored in the memory 207 to the connector 211. During transmission from the controller 201 to the connector 211 via a line, the data signal experiences channel loss and thus voltage reduction.

To compensate for voltage reduction of a data signal, the channel loss compensator 209 is interposed between the controller 201 and the connector 211, receives a data signal from the controller 201, and compensates for channel loss of the data signal. For example, the channel loss compensator 209 may be disposed as near to the connector 211 as possible, to thereby compensate for channel loss caused by the line between the controller 201 and the connector 211 as much as possible. If the channel loss is −6, −9, or −12 dB, the channel loss compensator 209 may compensate the data signal for −6, −9, or −12 dB.

Specifically, the channel loss compensator 209 may raise an output voltage swing level received from the controller 201 or an oscillator (not shown) or control the output voltage swing level within a predetermined range. For example, if the output voltage swing level is 0.9V, the channel loss compensator 209 may raise the output voltage swing level to a range of 1.0 to 1.2V. In another example, the channel loss compensator 209 may select a specific voltage from the range of 1.0 to 1.2V and then raise the output voltage swing level to the specific voltage.

The channel loss compensator 209 may compensate for channel loss of a data signal received from the controller 201 by amplifying the data signal according to the raised output voltage swing level and may output the compensated data signal to the connector 211.

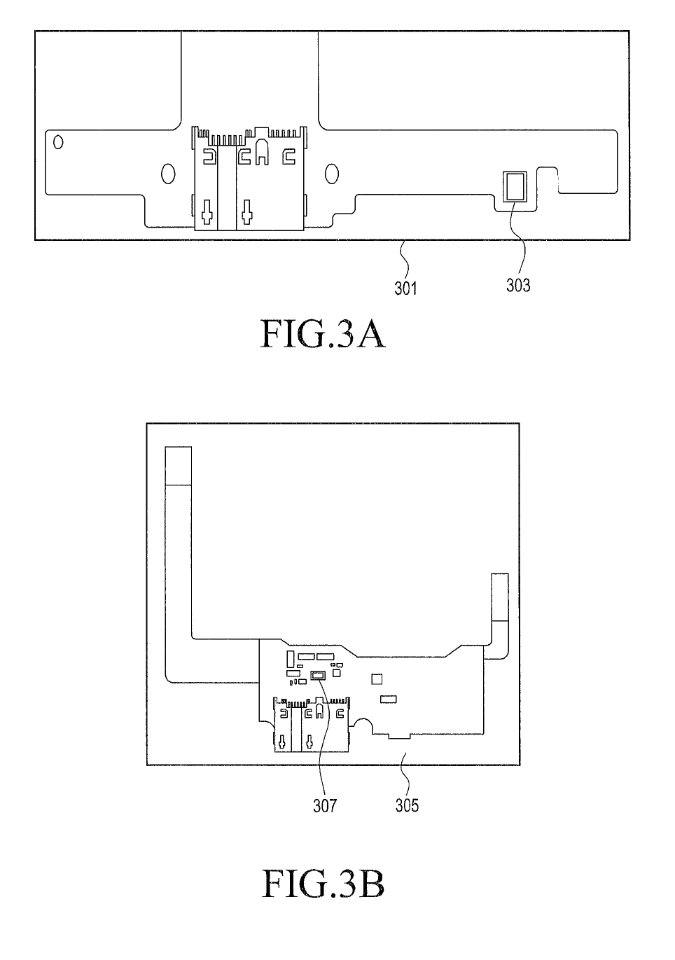

FIGS. 3A and 3B illustrate boards of electronic devices according to embodiments of the present disclosure.

Referring to FIG. 3A, if the electronic device 101 is a table computer, the electronic device 101 includes a board 301. The board 301 of the electronic device 101 includes a channel loss compensator 303 to compensate for channel loss between the controller 201 and the connector 211.

If the electronic device 101 is a hand-held phone (as shown in FIG. 3B), the electronic device 101 includes a board 305. The board 305 of the electronic device 101 includes a channel loss compensator 307 to compensate for channel loss between the controller 201 and the connector 211.

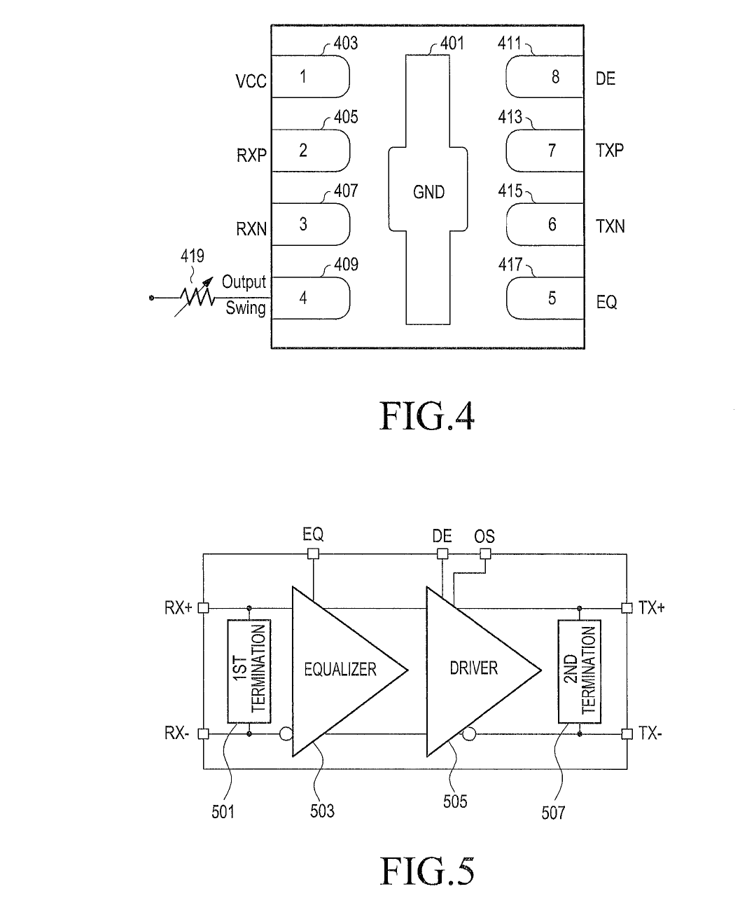

FIG. 4 illustrates a chip on which a channel loss compensator is implemented according to embodiments of the present disclosure.

Referring to FIG. 4, the chip of the channel loss compensator 209 may include a ground pin 401 (GND), a power pin 403 (VCC), data signal input pins 405 and 407 (RXP and RXN, respectively), an output voltage swing pin 409, a driver enable pin 411 (DE), data signal output pins 413 and 415 (TXP and TXN, respectively), and an equalizer pin 417 (EQ). The chip can further include a resistor 419 near to the connector 211.

The ground pin 401 (GND) is a pin for grounding the chip and the power pin 403 (VCC) is used to supply power to the chip. The data signal input pins 405 and 407 (RXP and RXN) receive data signals from the controller 201. The data signal output pins 413 and 415 (TXP and TXN) output data signals with channel loss compensated for.

The resistor 419 can be one of a pull-up resistor, a pull-down resistor, and a No Connection (NC) resistor, or can be a variable resistor that acts variably as a pull-up resistor, a pull-down resistor, and an NC resistor. For example, the resistor 419 may control an output voltage swing level received at 0.9 to 1.2V and outputs the controlled output voltage swing level. For example, if the output voltage swing level is 0.9V and the resistor 419 is a pull-up resistor, the resistor 419 may raise the output voltage swing level to a range of 1.0 to 1.2V. In another example, if the output voltage swing level is 0.9V and the resistor 419 is a variable resistor, the resistor 419 may raise the output voltage swing level to a range of 1.0 to 1.2V through control of a variable resistance value. In another example, if the resistor 419 is a variable resistor, the resistor 419 may control the output voltage swing level within the range of 1.0 to 1.2V through control of a variable resistance value. If the resistor 419 is designed as a pull-up resistor, a pull-down resistor, an NC resistor, or a variable resistor, its resistance value may be controlled in hardware or software by a user.

The output voltage swing pin 409 receives a controlled output voltage swing level, the driver pin 411 (DE) receives a first gain by which to amplify a data signal, and the equalizer pin 417 (EQ) receives a second gain by which to equalize a data signal.

FIG. 5 is a circuit diagram of a channel loss compensator according to embodiments of the present disclosure.

Referring to FIG. 5, the channel loss compensator 209 includes first and second terminations 501 and 507, an equalizer 503, and a driver 505.

The equalizer 503 receives a controlled output voltage swing level, receives a data signal through the first termination 501, primarily amplifies the data signal according to the controlled output voltage swing level, and outputs the primarily amplified data signal to the driver 505. The first termination 501 may prevent returning of the input data signal.

The driver 505 receives first and second gains, receives the primarily amplified data signal, secondarily amplifies the primarily amplified data signal according to the first and second gains, and outputs the secondarily amplified data signal to the connector 211 through the second termination 507. The second termination 507 may prevent the secondarily data signal from returning to the driver 505.

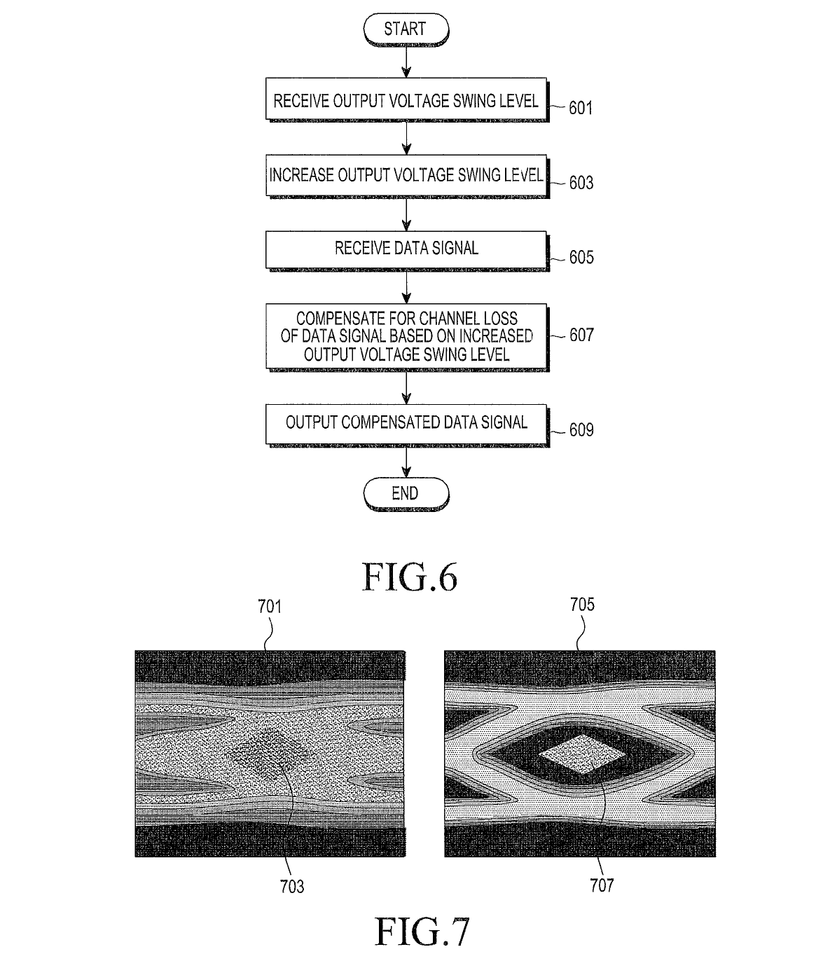

FIG. 6 illustrates a method for compensating for channel loss according to embodiments of the present disclosure.

Referring to FIG. 6, the channel loss compensator 209 receives an output voltage swing level in block 601 and proceeds to block 603. For example, the channel loss compensator 209 may receive an output voltage swing level lower than 1.0V.

In block 603, the channel loss compensator raises the output voltage swing level. For example, if the output voltage swing level is 0.9V, the channel loss compensator 209 may raise the output voltage swing level to a range of 1.0 to 1.2V.

The channel loss compensator 209 receives a data signal from the controller 201 in block 605 and compensates for channel loss of the data signal according to the raised output voltage swing level in block 607. The channel loss is caused by the line between the controller 201 and the connector 211.

In block 609, the channel loss compensator 209 outputs the channel loss-compensated data signal to the connector 211.

FIG. 7 illustrates eye patterns showing a channel loss compensation effect according to embodiments of the present disclosure. Specifically, FIG. 7 illustrates eye patterns of data signals transmitted from the controller 201 to the connector 211 via the line, as measured using measurement equipment. From the eye patterns, the impact of jitter and noise reflected in a signal output from the connector 211 can be confirmed.

Referring to FIG. 7, an eye pattern 701 represents a closed-eye waveform caused by channel loss of a data signal. The eye pattern 701 shows a waveform indicating signal attenuation and distortion of the data signal caused by jitter or noise, as an eye mask 703 generated inside the measurement equipment contacts a signal waveform. In an eye-closed case of the eye mask 703 as illustrated in the eye pattern 701, a data signal may experience data loss caused by channel loss.

An eye pattern 705 represents an eye waveform after channel loss of a data signal is compensated for. This eye waveform makes an eye mask 707 and a data signal waveform distinctive from each other, like an eye. As noted from the eye pattern 705, if the eye waveform is generated, the data signal does not experience channel loss-incurred data loss.

The proposed apparatus and method for compensating for channel loss in an electronic device can be implemented as computer-readable code in a computer-readable recording medium. The computer-readable recording medium can include any kind of recording device storing computer-readable data. Examples of the recording medium include Read Only Memory (ROM), Random Access Memory (RAM), optical disk, magnetic tape, floppy disk, hard disk, non-volatile memory, and the like, and can also include the medium that is implemented in the form of carrier waves (for example, transmission over the Internet). In addition, the computer-readable recording medium can be distributed over the computer systems connected over the network, and computer-readable codes can be stored and executed in a distributed manner.

According to embodiments of the present disclosure, each programming module can be configured in software, firmware, hardware, or a combination of at least two of them. The foregoing names of hardware components can be changed depending on the type of the electronic device. In embodiments of the present disclosure, hardware may be configured so as to include at least one the aforementioned components. Some components may be added to or removed from the hardware configuration. In addition, a part of the hardware components may be incorporated into a single entity that performs the same functions of the hardware components.

The controller 201 may include at least one Application Processor (AP) or at least one Communication Processor (CP). For example, if the controller 201 includes an AP and a CP, the AP and the CP can be included in one Integrated Circuit (IC) package or in different IC packages. The AP may control a plurality of hardware components or software components connected to the AP by driving an OS or an application program, and may process and operate various types of data including multimedia data. For example, the AP can be implemented as a System on Chip (SoC). In another embodiment of the present disclosure, the controller 201 may further include a Graphic Processing Unit (GPU).

As is apparent from the above description, various embodiments of the present disclosure compensate for channel loss using a channel loss compensator configured to compensate for channel loss of a data signal caused by a transmission line in an electronic device.

Although the present disclosure has been described with embodiments, various changes and modifications may be suggested to one skilled in the art. It is intended that the present disclosure encompass such changes and modifications as fall within the scope of the appended claims.

What is claimed is:

1. An apparatus for compensating for channel loss in an electronic device, the apparatus comprising:
a resistor configured to increase an output voltage swing level; and
a connector configured to:
receive a data signal,
compensate for channel loss of the received data signal by amplifying the received data signal based on an output voltage swing level, and
output the amplified data signal.

2. The apparatus of claim 1, further comprising a driver pin configured to re-amplify the amplified data signal based on a first gain and a second gain and to output the re-amplified data signal through the connector.

3. The apparatus of claim 2, wherein the driver pin is configured to receive the first gain by which to amplify the data signal.

4. The apparatus of claim 2, further comprising an equalizer pin configured to receive the second gain by which to equalize the data signal.

5. The apparatus of claim 1, wherein the channel loss is caused by a line between a controller and the connector.

6. The apparatus of claim 1, wherein the resistor is one of:
a pull-up resistor,
a pull-down resistor,
a No Connection (NC) resistor, and
a variable resistor having a variable resistance value that is changeable by a user.

7. The apparatus of claim 1, wherein the resistor and an equalizer pin configured to output the amplified data signal through the connector are positioned in a vicinity of the connector.

8. The apparatus of claim 1, wherein the connector is configured to support Universal Serial Bus (USB) 3.0 communication.

9. The apparatus of claim 1, wherein the resistor is configured to control the output voltage swing level and output a controlled output voltage swing level to an output voltage swing pin.

10. A method for compensating for channel loss in an electronic device, the method comprising:
increasing an output voltage swing level;
receiving a data signal and compensating for channel loss of the received data signal by amplifying the received data signal based on an output voltage swing level; and
outputting the amplified data signal through a connector.

11. The method of claim 10, further comprising:
re-amplifying the amplified data signal based on a first gain and a second gain; and
outputting the re-amplified data signal through the connector.

12. The method of claim 10, wherein the channel loss is caused by a line between a controller and the connector.

13. The method of claim 10, wherein the connector is configured to support Universal Serial Bus (USB) 3.0 communication.

14. The method of claim 10, further comprising:
controlling the output voltage swing level and outputting a controlled output voltage swing level to an output voltage swing pin.

15. A non-transitory computer readable recording medium storing one or more programs that comprise instructions that, when executed by processing circuitry, causes the processing circuitry to:
increase an output voltage swing level;
receive a data signal and compensate for channel loss of the received data signal by amplifying the received data signal based on an output voltage swing level; and
output the amplified data signal through a connector.

16. The non-transitory computer readable recording medium of claim 15, wherein the one or more programs further comprise instructions that, when executed by processing circuitry, causes the processing circuitry to:
re-amplify the amplified data signal based on a first gain and a second gain; and
output the re-amplified data signal through the connector.

17. The non-transitory computer readable recording medium of claim 16, wherein the instructions that cause the processing circuitry to re-amplify the amplified data signal based on a first gain and a second gain further comprise instructions that, when executed by processing circuitry, causes the processing circuitry to:
receive, by a driver pin, the first gain by which to amplify the data signal

18. The non-transitory computer readable recording medium of claim 16, wherein the instructions that cause the processing circuitry to re-amplify the amplified data signal based on a first gain and a second gain further comprise instructions that, when executed by processing circuitry, causes the processing circuitry to:
receive, by an equalizer, the second gain by which to equalize the data signal.

19. The non-transitory computer readable recording medium of claim 15, wherein the instructions that cause the processing circuitry to increase an output voltage swing level comprise instructions that, when executed by processing circuitry, causes the processing circuitry to:

20. The non-transitory computer readable recording medium of claim 15, wherein the channel loss is caused by a line between a controller and a connector.
